(19) United States
(12) Patent Application Publication
(10) Pub. No.: US 2007/0266948 A1
(43) Pub. Date: Nov. 22, 2007

(54) Device for Controlling Electron Temperature in an Ecr Plasma

(76) Inventors: Denis Hitz, Grenoble (FR); David Cormier, Riom (FR)

Correspondence Address: Brinks Hofer Gilson & Lione, P.O. Box 10395, Chicago, IL, 60610, US

(21) Appl. No.: 10/578,529

(22) PCT Filed: Nov. 3, 2004
(86) PCT No.: PCT/FR04/02821

§ 371 Date: Jun. 15, 2007

(30) Foreign Application Priority Data
Nov. 4, 2003 (FR) 0312934

(51) Int. Cl. C23C 16/00; H05H 1/18; C23F 1/00; H01L 21/306

(52) U.S. Cl. 118/723 MA; 118/723 R; 156/345.36

(57) ABSTRACT

A device which is used to control the electronic temperature in an ECR plasma chamber includes at least one moderator which is placed in the path of electrons having an energy greater than a pre-determined energy, so as to form an obstacle to the electrons. The invention is suitable for use in ion sources and plasma machines.

### PRIORITY CLAIM

This application claims priority to French Patent Application No. 0312934 filed Nov. 4, 2003.

### TECHNICAL FIELD

The invention relates, in general, to the production of currents of multicharged ions in a plasma chamber, such as an ECR ion source or a plasma machine. The invention relates more particularly to a device for controlling electron temperature in an ECR plasma.

### BACKGROUND

The function of electron cyclotron resonance (ECR) “ion sources” is to produce, firstly, ionic currents in the μA to mA range and, secondly, a range of extended charge states. Users of these sources at present demand several mA of ions of low electrical charge, like B¹⁺ to B³⁺ (serving as implanters), about 1 mA of ions of moderate charge, like Ar⁸⁺, Ar¹²⁺ or Pb²⁷⁺ (feeding accelerators for nuclear physics), and a few μA of ions of very high charge, like Ar¹⁶⁺, Ar¹⁷⁺ or Ar¹⁸⁺ (feeding accelerators for nuclear physics or atomic physics).

The function of ECR “plasma machines” is to produce ions that are not extracted from the machine. Those ions are used to deposit materials on substrates, for example.

In an ECR plasma chamber, the plasma (combination of ions and electrons) is confined in an enclosure immersed in a magnetic configuration resulting from the superposition of two magnetic fields, one axial and the other radial, with the aim of preventing plasma leaks. All the electrons of the plasma oscillate on magnetic field lines that are easy to calculate using various codes (see, for example, the paper by A. Girard et al. “Electron Cyclotron Resonance Ion Sources: Experiments and Theory”, 12th International Seminar on ECR ion sources, 25-27 Apr. 1995, Riken, Japan).

To produce ions of charge q+, an ECR plasma uses the principle of repetitive “plucking” of atoms that results from collisions between those atoms and energetic electrons. It is estimated empirically that the energy required for those electrons must be equal to approximately three times the ionization potential of the X^{(q-1)+} ion. Accordingly, the ionization potential of argon atoms being 16 eV, the optimum electron energy for producing Ar⁺ ions is about 100 eV; to produce Ar⁸⁺ ions, electrons are required having an energy close to 500 eV, whereas to produce Ar¹⁸⁺ ions the electrons must have an energy of the order of 15 keV.

The ever increasing ionic currents required by users make it necessary to improve ECR ion sources. Various approaches to this have been explored. These include:

1) increasing the electron heating frequency: this increases the density of the electrons in the plasma, in accordance with a law that is well known in plasma physics;

2) optimizing the confinement of the electrons and ions of the plasma: much work has been done in this area, see for example the paper by S. Gammino et al. “Operation of the Serse superconducting ECR ion source at 28 GHz” (Review of Scientific Instruments, vol. 72, N° 11, p. 4090, November 2001); this paper discloses scaling laws linked to the confinement of the plasma;

3) optimizing the injection of microwaves: see for example the patent FR 2 681 186; and

4) reducing the temperature of the ions by injecting a gas lighter than the gas to be ionized (gas mixing technique): see the paper by A. Drentje “Techniques to improve highly charged ions output from ECRISs” (15th International Seminar on ECR ion sources, University of Jyväskylä, Finland, June 2002).

Measurements of electron temperature Tₑ have been effected. It has been shown (see, for example, the paper by A. Girard et al. cited above) that, in an ECR plasma, there co-exist a population of “very hot” electrons (Tₑ>50 keV), a population of “hot” electrons (1 keV<Tₑ<50 keV) and a population of “cold” electrons (Tₑ<1 keV). In fact, only the hot electrons having a temperature less than 20 keV are usable in an ECR plasma (for example, to obtain Ar¹⁸⁺ ions requires electrons of about 15 keV, as indicated above). Presently, electrons of energy greater than 100 keV are routinely found in an ECR plasma: those electrons are entirely ineffective because their energy is too much higher than the optimum energy.

### SUMMARY

The invention therefore relates to an ECR plasma chamber comprising an enclosure immersed in a magnetic configuration resulting from the superposition of two magnetic fields, one axial and the other radial, wherein the configuration of the electron trajectories depends on said magnetic configuration, said ECR plasma chamber being noteworthy in that it comprises at least one moderator whose position and shape are chosen as a function of said magnetic configuration so that said moderator constitutes an obstacle to electrons whose energy is greater than a predetermined energy.

Accordingly, depending on their position in the plasma chamber and their shape, the above moderators stop the more or less energetic electrons, which reduces the number of electrons judged too hot, or even completely eliminates them, by placing obstacles on their path. In particular, by using the moderators of the invention to cover a wider or narrower region in the plasma chamber, the range of energy of the electrons to which they constitute an obstacle may be determined.

In accordance with the invention, the electron temperature can be controlled so that it coincides with the ionization potentials of the ions concerned. Furthermore, if the ions or electrons of the plasma touch the moderators, secondary electrons of low energy (a few eV) are created; those electrons are then immediately heated and advantageously contribute to the ionization process.

According to particular features of the invention, the position and number of said moderators are chosen as a function of the energy and the number of electrons to which an obstacle is required. As a result of these provisions greater or lesser quantities of the undesirable electrons may be eliminated.

According to other particular features of the invention, the materials constituting the moderators are chosen as a function of their aptitude to produce secondary electrons when they are subjected to collisions with high-energy electrons.

In fact, depending on the materials used for the moderators, the number and the energy of the secondary electrons produced in this way may be higher or lower. The effect of these secondary electrons on the production of ions can therefore be controlled.

According to other particular features of the invention, the moderator comprises at least one active portion and a ring encircling the plasma.

A robust device is obtained in this way, which enables said active particles to be placed conveniently in the best possible position as a function of the magnetic configuration concerned.

The invention is also directed to an ECR ion source and an ECR plasma machine advantageously comprising any of the plasma chambers succinctly described above.

Other aspects and advantages of the invention will become apparent on reading the following detailed description of particular embodiments provided by way of nonlimiting example.

### BRIEF DESCRIPTION OF THE DRAWING

FIG. 1 is a sectional view of a plasma chamber,

FIGS. 2a and 2b are sectional views of a plasma chamber equipped with a moderator in accordance with an embodiment of the invention placed in a plasma-free region of the chamber, with moderators of two different shapes,

FIG. 3 is a sectional view of a plasma chamber equipped with a moderator in accordance with an embodiment of the invention placed in a plasma leakage region,

FIG. 4 is a sectional view of a plasma chamber equipped with a moderator in accordance with an embodiment of the invention placed in the hot plasma region of the chamber,

FIG. 5 illustrates one example of the structure of a moderator in accordance with an embodiment of the invention, and

FIG. 6 is a perspective view of a plasma chamber equipped with moderators according to FIG. 5.

### DETAILED DESCRIPTION

Various embodiments of the invention will now be described.

As indicated above, the magnetic profile of an ECR plasma chamber is given by the superposition of two magnetic fields (axial and radial). The structure of those magnetic fields determines the shape of the plasma, and is therefore chosen as a function of the target application. For example, if the aim is to impart to the plasma a shape that is as cylindrical as possible, a radial magnetic field with 2n poles is produced; the region in which the electrons circulate is then the shape of a star with n branches.

FIG. 1 is a view in section of a plasma chamber 1 in the case of radial confinement obtained by means of six magnetic poles 2a to 2f (in which case the region in which the electrons circulate, not shown, is the shape of a star with three branches).

Three types of regions are distinguished in the plasma chamber 1:

1) []-]] a central region 3 of the plasma (essentially comprising “hot” electrons and “cold” ions),

2) [[-]] plasma leakage regions 4, and

3) [[-]] plasma-free regions 5.

Note that very hot electrons may be found in all these regions, including the plasma-free regions 5.

As indicated above, the theoretical tools necessary for determining the electron trajectories (as well as the overall shape of the plasma) as a function of the target application are now available; the following procedure may be adopted:

a) the configuration of the axial magnetic field and of the radial magnetic field is calculated,

b) the total magnetic configuration is calculated, and

c) there is obtained the envelope of the magnetic field lines around which the electrons in the ECR plasma wind.

Once the electron trajectories have been determined in this way, the position, shape and materials required for moderators in accordance with the invention may be determined.

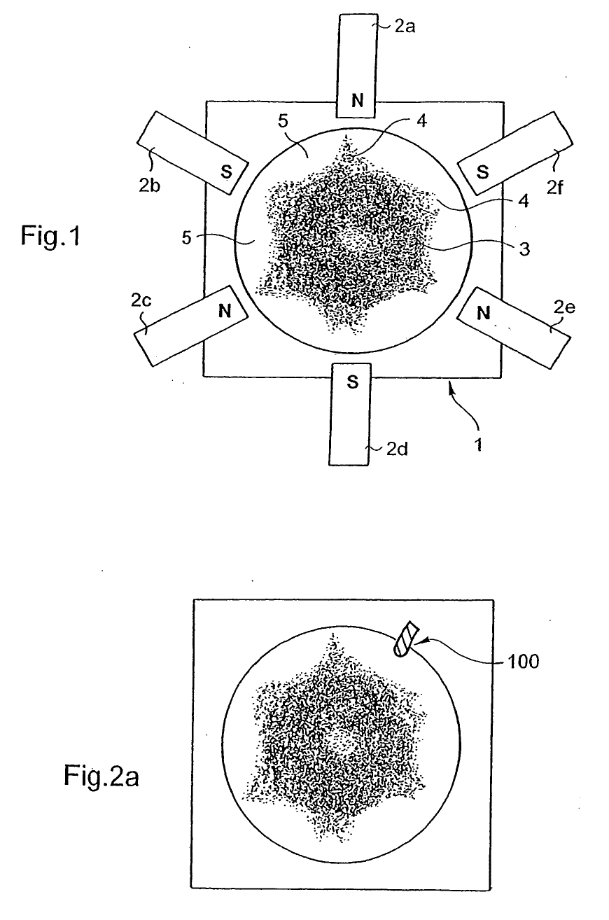

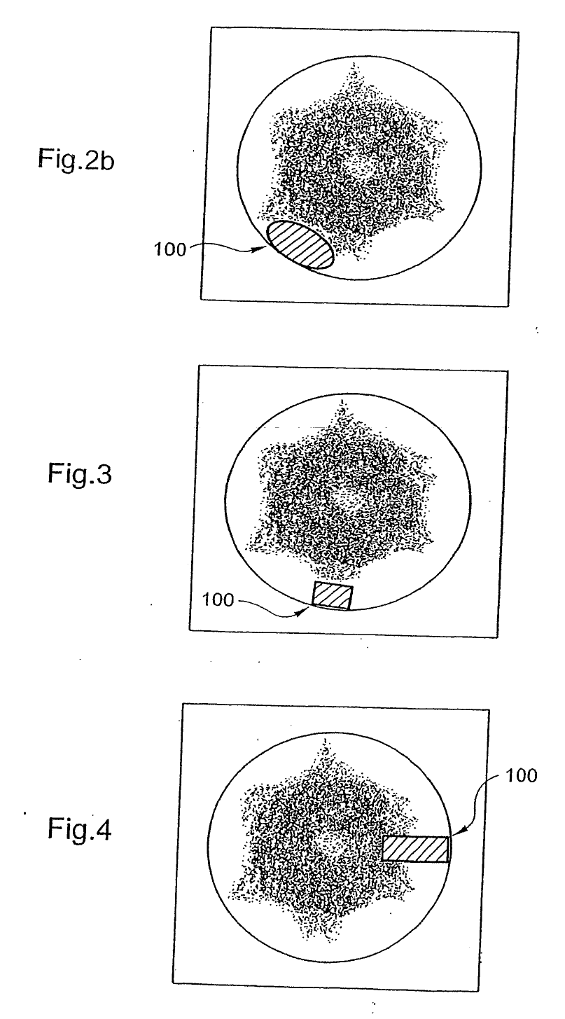

FIGS. 2a and 2b are views in section of a plasma chamber 1 equipped with a moderator 100 placed in a plasma-free region 5 of the chamber, with moderators of two different shapes. The relatively wider shape of the FIG. 2b moderator intercepts electrons on a greater number of trajectories.

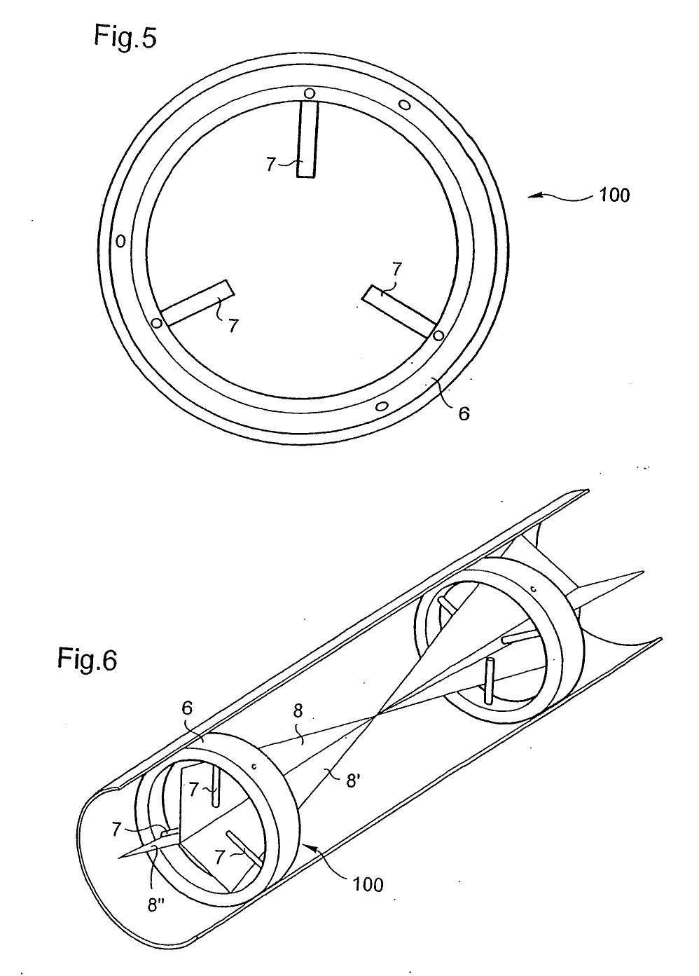

FIG. 3 is a view in section of a plasma chamber 1 equipped with a moderator 100 placed in a plasma leakage region 4 and FIG. 4 is a view in section of a plasma chamber 1 equipped with a moderator 100 intercepting the central region 3 of the chamber.

Only one moderator 100 is shown in each of FIGS. 2a, 2b, 3 and 4, by way of example. However, it is clear that in many cases it is necessary to use several moderators 100 to obtain the required electron temperature. In particular, when the radial magnetic field has 2n poles, the moderator 100 preferably has n active portions 7 (shown in FIGS. 5 and 6) each of which is placed in a respective one of the n branches formed by the electron trajectories.

It will further be noted that, although high-energy electrons are present throughout the plasma chamber 1, their concentration is evidently at a maximum in the central region 3, in which the temperatures of the plasma are themselves at a maximum. For optimum efficacy of the moderators 100, the aim will therefore also be to place them as close as possible to the central region 3, but it will be necessary to take account, in particular, of the temperature that the structure of the moderator 100 can withstand.

FIG. 5 represents one example of a structure for a moderator of the invention intended to be placed in a plasma chamber having a hexapolar magnetic configuration. The structure includes three active portions 7, each of which is in the form of a cylindrical rod intended to be placed radially in a transverse plane of the plasma chamber 1 with one end of the rod pointing toward the central region 3 of the chamber and the other end fixed to another portion of the moderator 100 consisting of a ring 6 intended to encircle the plasma.

In another embodiment (not shown), the active portion 7 of the moderator 100 is fixed, for the purposes of mechanical retention, to an intermediate portion that is in turn fixed to a ring 6 of the type used in the previous embodiment. For example, the intermediate portion may consist of a support rod and the active portion 7, which may take the form of a rod, disc or ball, is mounted at the end of that support rod.

The thickness of the rings 6 must be sufficient to hold the active portions sufficiently rigidly, but must not be too large, to avoid disturbing the plasma. For example, a thickness from 2 to 5 mm is generally suitable for a 100 mm diameter plasma chamber.

The person skilled in the art will select active portions 7 of greater or lesser size (for example the diameter of the FIG. 5 rods) as a function, in particular, of the required rate of production of secondary electrons when very hot electrons impact on the active portions 7; the secondary electrons produced in this way are generally cold electrons. If it is found that an excessively high number of hot electrons is present, for example, the person skilled in the art will increase the size of the active portions 7 accordingly.

It will be noted that, in service, the end of the active portion 7 nearest the central region 3 of the plasma erodes through contact therewith, which affects its shape. For example, if the active portion 7 is a rod whose end is initially flat, and if the plasma has a concave shape at that end, the end of the rod will assume a concave shape in service.

The various component parts of the moderators 100 can be made from various materials.

The rings 6 must obviously be made from materials with no risk of melting in service; moreover, these materials must preferably not give off gases. The rings 6 may be made of metal or ceramic (such as alumina or zirconium oxide), for example.

If intermediate parts are used, such as support rods, they are subject to the same material constraints as the rings 6.

Finally, the active portions 7 should preferably be able to withstand the high temperatures present in the plasma (whereas the other portions of the moderators 100, which are intended to provide mechanical support for the active portions 7, and are, firstly, farther away from the hot portions of the plasma and, secondly, protected to some degree by those active portions 7, require lesser precautions in this regard). The active portions 7 are preferably made of a refractory material, such as tungsten, tantalum or molybdenum; however, they could equally be made of a ceramic (such as alumina, zirconium oxide or thorium oxide) or made entirely of metal.

The number and energy of the secondary electrons produced by the impact of very hot electrons will be different according to the materials chosen for the moderators. The person skilled in the art will therefore select materials adapted to his requirements, if necessary after a limited number of in situ tests.

FIG. 6 is a perspective view of a hexapolar radial confinement plasma chamber 1 equipped with a certain number of modulators 100 of the type shown in FIG. 5. As can be seen in FIG. 6, the rods 7 are contained within regions 8, 8′, 8″ in which unwanted electrons circulate.

1. An ECR plasma chamber comprising:
an enclosure immersed in a magnetic configuration resulting from the superposition of an axial magnetic field and a radial magnetic field, wherein electron trajectories depends on the magnetic configuration; and
at least one moderator having a position and shape in relation to the magnetic configuration such that the at least one moderator constitutes an obstacle to electrons whose energy is greater than a predetermined energy.

2. The ECR plasma chamber according to claim 1, wherein the position of the at least one moderator within the magnetic configuration relates to the energy and the number of electrons to which an obstacle is required.

3. The ECR plasma chamber according to claim 1, wherein the materials of construction of the at least one moderator comprises materials that produce secondary electrons when they are subjected to collisions with high-energy electrons.

4. The ECR plasma chamber according to claim 1, wherein the radial mag netic field includes 2n poles and the at least one moderator includes n active portions each of which is placed in a respective one of n branches formed by the electron trajectories.

5. The ECR plasma chamber according to claim 1, wherein the at least one moderator comprises at least one active portion and a ring encircling the plasma.

6. The ECR plasma chamber according to claim 5, wherein the active portion comprises a cylindrical rod radially located in a transverse plane of the plasma chamber, wherein a first end of the rod points toward a central region of the plasma chamber and a second end of the rod is fixed to the ring.

7. The ECR plasma chamber according to claim 5, wherein the at least one active portion is mounted at the end of a support rod, and wherein the support rod is itself fixed to the ring.

8. The ECR plasma chamber according to claim 1, wherein at least a portion of the at least one moderator comprises a metal structure.

9. The ECR plasma chamber according to claim 1, wherein at least a portion of the at least one moderator comprises a ceramic structure.

10. An ECR ion source comprising an ECR plasma chamber according to claim 1.

11. An ECR plasma machine comprising an ECR plasma chamber according to claim 1.
